(19) United States
(12) Patent Application Publication
(10) Pub. No.: US 2004/0257774 A1
(43) Pub. Date: Dec. 23, 2004

(54) Heat-dissipating fan device with light-emitting capability

(76) Inventor: Hao-Cheng Lin, Taipei City (TW)

Correspondence Address: LADAS & PARRY, 5670 WILSHIRE BOULEVARD, SUITE 2100, LOS ANGELES, CA, 90036-5679, US

(21) Appl. No.: 10/600,378

(22) Filed: Jun. 20, 2003

(51) Int. Cl. H05K 7/20

(52) U.S. Cl. 361/719

(57) ABSTRACT

In a heat-dissipating fan device, a fan housing has a base wall, and a surrounding wall extending from the basewall. A circuit board is disposed in the fan housing and is mounted on the base wall. A fan impeller is mounted on the circuit board and is rotatable about a central axis that is transverse to the circuit board. The fan impeller is formed with a plurality of radial fan blades. A plurality of light emitting diodes are surface-mounted on the circuit board and are arranged around the fan impeller.

### BACKGROUND OF THE INVENTION

1. Field of the Invention

The invention relates to a heat-dissipating fan device, more particularly to a heat-dissipating fan device with a light-emitting capability.

2. Description of the Related Art

FIG. 1 illustrates a conventional heat-dissipating fan device that includes a fan housing 11, a circuit board 12, a fan impeller 13, and a plurality of light emitting diodes 14. The fan housing 11 has a base wall, and a surrounding wall 111 extending from the base wall. The surrounding wall 111 has an inner surface 1110 formed with a plurality of diode-mounting holes 112 that extend radially from the inner surface 1110. The circuit board 12 is disposed in the fan housing 11, and is mounted on the base wall. The circuit board 12 is coupled electrically to a power wire 10 by soldering. The fan impeller 13 is mounted on the circuit board 12, and is rotatable about a central axis 15 that is transverse to the circuit board 12. The fan impeller 13 includes a plurality of radial fan blades 131. The diodes 14 are received and mounted in the diode-mounting holes 112, respectively.

It is noted that, during fabrication, the surrounding wall 111 of the fan housing must be formed with the diode-mounting holes 112, and the diodes 14 and the power wire 10 must be coupled to the circuit board 12 by wire-soldering, thereby resulting in a relatively complicated fabrication process. Furthermore, the diodes 14 emit light along radial directions transverse to the central axis 15, thereby resulting in a poor light-emitting effect.

### SUMMARY OF THE INVENTION

Therefore, the object of the present invention is to provide a heat-dissipating fan device that has a better light-emitting effect and that can be fabricated through a relatively simple process.

According to the present invention, a heat-dissipating fan device comprises:

a fan housing having a base wall, and a surrounding wall extending from the base wall;

a circuit board disposed in the fan housing and mounted on the base wall;

a fan impeller mounted on the circuit board and rotatable about a central axis that is transverse to the circuit board, the fan impeller being formed with a plurality of radial fan blades; and

a plurality of light emitting diodes surface-mounted on the circuit board and arranged around the fan impeller.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of a conventional heat-dissipating fan device;

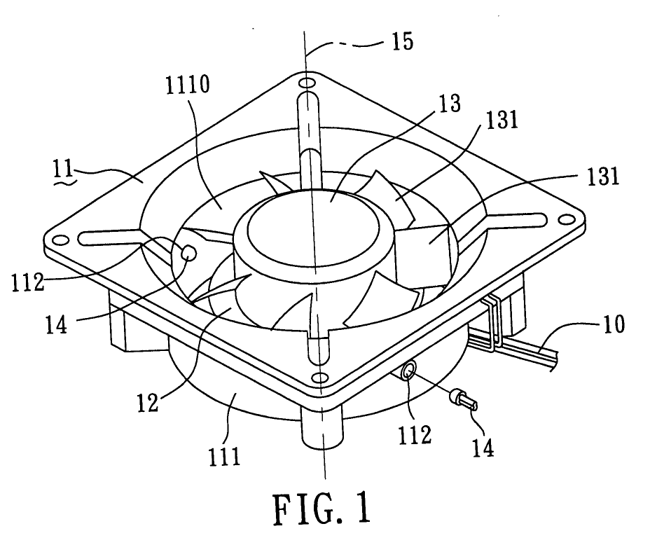

FIG. 2 is an exploded perspective view showing the preferred embodiment of a heat-dissipating device according to the present invention;

FIG. 3 is a schematic top view of the preferred embodiment; and

FIG. 4 is a schematic electrical circuit diagram illustrating a control unit and light emitting diodes of the preferred embodiment.

### DETAILED DESCRIPTION OF THE PREFERRED EMBODIMENT

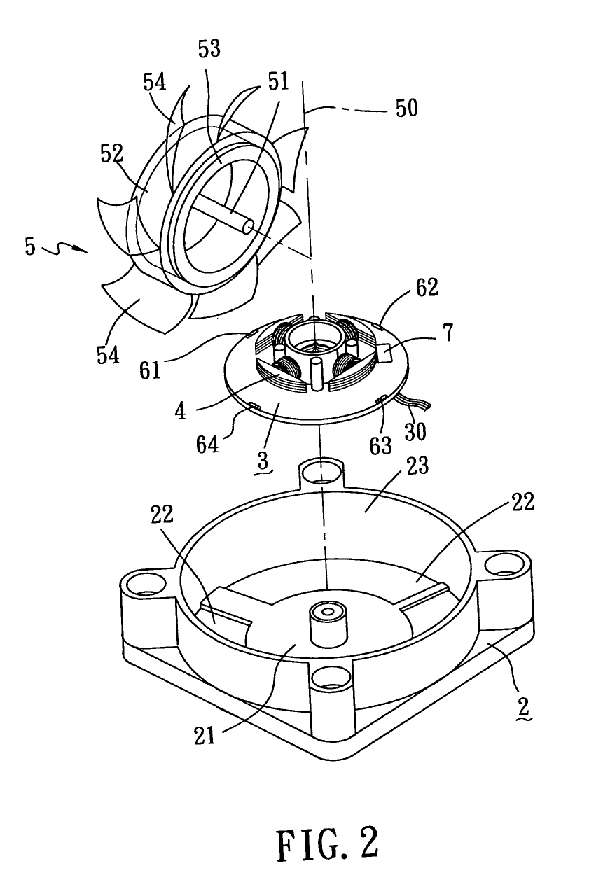

Referring to FIG. 2, the preferred embodiment of a heat-dissipating fan device according to the present invention is shown to include a fan housing 2, a circuit board 3, a fan impeller 5, a plurality of light emitting diodes 61, 62, 63, 64, and a control unit 7.

The fan housing 2 has a base wall 21 formed with a plurality of vent holes 22, and a surrounding wall 23 extending from the base wall 21.

The circuit board 3 is disposed in the fan housing 2, and is mounted on the base wall 21, such as with the use of adhesive. A set of fan coils 4 is disposed on a central portion of the circuit board 3. The circuit board 3 is coupled electrically to a power wire 30.

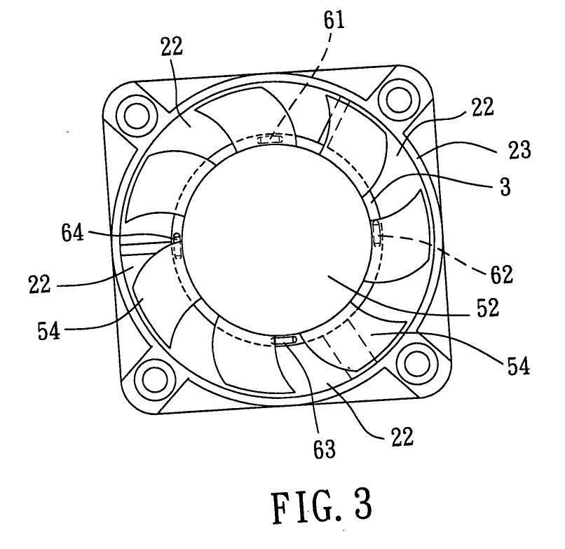

The fan impeller 5 is mounted on the circuit board 3, and is rotatable about a central axis 50 that is transverse to the circuit board 3. The fan impeller 5 includes a transparent fan cap 52 that has an outer radial surface and that is formed with a plurality of radial fan blades 54, and a central axle 51 disposed in the fan cap 50 and extending from the fan cap 52 along the central axis 50. A magnetic ring member 53 is mounted in the fan cap 52 and is disposed around the set of coils 4. Accordingly, electrical current flowing through the fan coils 4 can drive rotation of the fan impeller 5 in a known manner. In this embodiment, the fan blades 54 are made of a transparent material. The fan cap 52 has an outer diameter smaller than a diameter of the circuit board 3, as shown in FIG. 3.

The light emitting diodes 61, 62, 63, 64 are surface-mounted on the circuit board 3 through known surface mounting techniques (SMT), and are arranged around the fan impeller 5. In this embodiment, the light emitting diodes 61, 62, 63, 64 can emit red, yellow, blue, and green lights, respectively.

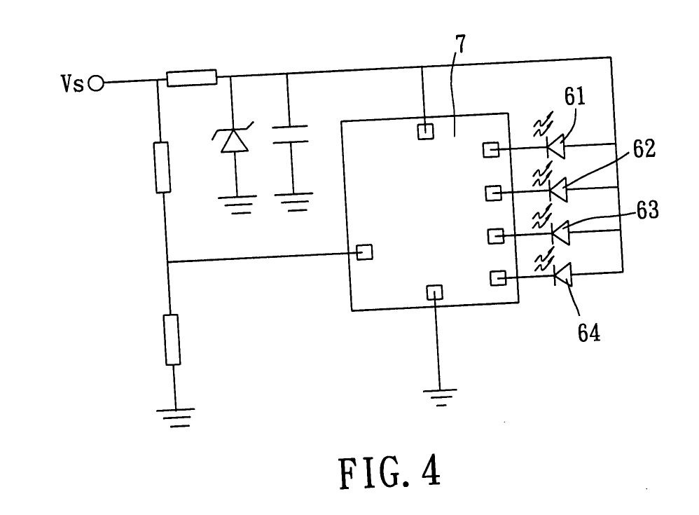

Referring further to FIG. 4, the control unit 7 is mounted on the circuit board 3, and is coupled electrically to the light emitting diodes 61, 62, 63, 64 so as to control activation of the light emitting diodes 61, 62, 63, 64. An operating voltage (Vs) from a power source is supplied to the control unit 7 via the power wire 30. In this embodiment, the control unit 7 is configured to control activation of the light emitting diodes 61, 62, 63, 64 in accordance with the operating voltage (Vs) from the power source. For example, when the operating voltage (Vs) is within a range of 6-7.9 Volts, the diodes 61, 63 are alternately activated to at a blinking frequency of 3 Hz. When the operating voltage (Vs) is within a range of 8-9.9 Volts, the diodes 62, 64 are alternately activated at a blinking frequency of 3 Hz. When the operating voltage (Vs) is within a range of 10-11.9 Volts, the diodes 61, 62 are alternately activated at a blinking frequency of 3 Hz, and the diodes 63, 64 are alternately activated at a blinking frequency of 3 Hz at the same time. When the operating voltage (Vs) is greater than 12 volts, the diodes 61, 62, 63, 64 are first activated to blink in sequence, and are then activated to blink simultaneously.

It is noted that the number of the diodes, the colors of emitting light emitted by the diodes, and the blinking status and conditions are not limited to those of the preferred embodiment, and can be changed as desired.

Since the diodes 61, 62, 63, 64 are surface-mounted on the circuit board 3, the formation of mounting holes in the fan housing 2 for receiving the diodes 61, 62, 63, 64, and wire soldering for coupled the diodes 61, 62, 63, 64 to the control unit 7 can be omitted as compared to the aforesaid conventional heat-dissipating fan device, thereby resulting in a simpler fabrication process. Moreover, the diodes 61, 62, 63, 64 can emit light in directions parallel to the central axis 50 such that a better light-emitting effect can be obtained. Furthermore, by monitoring the blinking status of the diodes 61, 62, 63, 64, the range of the operating voltage (Vs) can be known to facilitate inspection and maintenance of a power system.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A heat-dissipating fan device comprising:
a fan housing having a base wall, and a surrounding wall extending from said base wall;
a circuit board disposed in said fan housing and mounted on said base wall;
a fan impeller mounted on said circuit board and rotatable about a central axis that is transverse to said circuit board, said fan impeller being formed with a plurality of radial fan blades; and
a plurality of light emitting diodes surface-mounted on said circuit board and arranged around said fan impeller.

2. The heat-dissipating fan device as claimed in claim 1, further comprising a control unit mounted on said circuit board and coupled electrically to said light emitting diodes so as to control activation of said light emitting diodes.

3. The heat-dissipating fan device as claimed in claim 2, wherein said control unit is configured to control activation of said light emitting diodes in accordance with operating voltage from a power source.

4. The heat-dissipating fan device as claimed in claim 1, wherein said fan blades are made of a transparent material.
